(19) United States
(12) Patent Application Publication
(10) Pub. No.: US 2026/0018487 A1
(43) Pub. Date: Jan. 15, 2026

(54) MOLD COMPOUND EMBEDDED DEVICE COOLING STRUCTURE

(71) Applicant: QUALCOMM Incorporated, San Diego, CA (US)

(72) Inventors: Le GAO, San Diego, CA (US); Youmin YU, Escondido, CA (US); Nader NIKFAR, San Diego, CA (US)

(21) Appl. No.: 18/767,029

(22) Filed: Jul. 9, 2024

(51) Int. Cl. H01L 23/427; H01L 23/00; H01L 23/31; H01L 23/433; H01L 25/065

(52) U.S. Cl. CPC H01L 23/427; H01L 23/3128; H01L 23/433; H01L 24/32; H01L 25/0655; H01L 2224/32245

(57) ABSTRACT

A packaged integrated circuit device includes a semiconductor die. The packaged integrated circuit device also includes a sealed two-phase cooling structure thermally coupled to the semiconductor die. The packaged integrated circuit device further includes a mold compound encapsulating the semiconductor die and the sealed two-phase cooling structure.

### FIELD

Various features relate to thermal management in integrated circuit devices.

### DESCRIPTION OF RELATED ART

Electrical connections exist at each level of a system hierarchy. This system hierarchy includes interconnection of active devices at a lowest system level all the way up to system level interconnections at the highest level. For example, interconnect layers can connect different devices together on an integrated circuit. As integrated circuits become more complex, more interconnect layers are used to provide the electrical connections between the devices. More recently, the number of interconnect levels for circuitry has substantially increased due to the large number of devices that are now interconnected in a modern electronic device. The increased number of interconnect levels for supporting the increased number of devices involves more intricate processes.

State-of-the-art mobile application devices demand a small form factor, low cost, a tight power budget, and high electrical performance. With technological advancements, such as generative artificial intelligence, that process a large amount of data in a short time, the amount of heat generated by mobile device components is increasing. These devices are susceptible to uneven heating and overheating with one or more heat sources arranged within a small form factor.

### SUMMARY

Various features relate to integrated circuit devices.

One example provides a packaged integrated circuit device that includes a semiconductor die. The packaged integrated circuit device also includes a sealed two-phase cooling structure thermally coupled to the semiconductor die. The packaged integrated circuit device further includes a mold compound encapsulating the semiconductor die and the sealed two-phase cooling structure.

Another example provides a device that includes a packaged integrated circuit device and a printed circuit board (PCB) electrically connected to the packaged integrated circuit device. The packaged integrated circuit device includes a semiconductor die. The packaged integrated circuit device also includes a sealed two-phase cooling structure thermally coupled to the semiconductor die. The packaged integrated circuit device further includes a mold compound encapsulating the semiconductor die and the sealed two-phase cooling structure.

Another example provides a method of fabricating a packaged integrated circuit device, the method includes thermally coupling a sealed two-phase cooling structure to a semiconductor die. The method also includes using a mold compound to encapsulate the sealed two-phase cooling structure and the semiconductor die.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates a cross-sectional profile view of an exemplary device that includes a mold compound embedded device cooling structure.

FIG. 2 illustrates a cross-sectional profile view of an exemplary device that includes a mold compound embedded device cooling structure.

FIG. 3A illustrates a cross-sectional profile view of the cooling structure of either of the devices of FIGS. 1-2.

FIG. 3B illustrates an example of a vapor chamber as the cooling structure of either of the devices of FIGS. 1-2.

FIG. 3C illustrates an example of heat pipes as the cooling structure of either of the devices of FIGS. 1-2.

FIG. 4 illustrates a mobile device that may integrate either of the devices of FIGS. 1-2.

FIG. 5A illustrates a cross-sectional profile view of an exemplary device that includes a mold compound embedded device cooling structure thermally coupled to multiple dies.

FIG. 5B illustrates a cross-sectional profile view of an exemplary device that includes a mold compound embedded device cooling structure thermally coupled to multiple dies.

FIG. 6A illustrates a cross-sectional profile view of an exemplary device that includes multiple mold compound embedded device cooling structures thermally coupled to a single die.

FIG. 6B illustrates a cross-sectional profile view of an exemplary device that includes multiple mold compound embedded device cooling structures thermally coupled to a single die.

FIG. 7A illustrates a cross-sectional profile view of an exemplary device that includes multiple mold compound embedded device cooling structures thermally coupled to multiple dies.

FIG. 7B illustrates a cross-sectional profile view of an exemplary device that includes multiple mold compound embedded device cooling structures thermally coupled to multiple dies.

FIG. 8 illustrates an exemplary sequence for fabricating an exemplary device that includes a mold compound embedded device cooling structure.

FIG. 9 illustrates an exemplary sequence for fabricating an exemplary device that includes a mold compound embedded device cooling structure.

FIG. 10 illustrates an exemplary sequence for fabricating an exemplary device that includes a mold compound embedded device cooling structure.

FIG. 11 illustrates exemplary devices that include a mold compound embedded device cooling structure.

FIG. 12 illustrates an exemplary flow diagram of a method of semiconductor fabrication for a device that includes a mold compound embedded device cooling structure.

FIG. 13 illustrates various electronic devices that may integrate an exemplary mold compound embedded device cooling structure described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure. As another example, various devices and structures disclosed herein are illustrated schematically. Such schematic representations are not to scale and are generally intentionally simplified. To illustrate, integrated devices can have many tens or hundreds of contacts and corresponding interconnections; however, a very small number of such contacts and interconnects are illustrated herein to highlight important features of the disclosure without unduly complicating the drawings.

Particular aspects of the present disclosure are described below with reference to the drawings. In the description, common features are designated by common reference numbers. As used herein, various terminology is used for the purpose of describing particular implementations only and is not intended to be limiting of implementations. For example, the singular forms “a,” “an,” and “the” are intended to include the plural forms as well, unless the context clearly indicates otherwise. Further, some features described herein are singular in some implementations and plural in other implementations. For ease of reference herein, such features are generally introduced as “one or more” features and are subsequently referred to in the singular or optional plural (as indicated by “(s)”) unless aspects related to multiple of the features are being described.

As used herein, the terms “comprise,” “comprises,” and “comprising” may be used interchangeably with “include,” “includes,” or “including.” As used herein, “exemplary” indicates an example, an implementation, and/or an aspect, and should not be construed as limiting or as indicating a preference or a preferred implementation. As used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). As used herein, the term “set” refers to one or more of a particular element, and the term “plurality” refers to multiple (e.g., two or more) of a particular element.

Improvements in manufacturing technology and demand for lower cost and more capable electronic devices has led to increasing complexity of ICs. Often, more complex ICs have more complex interconnection schemes to enable interaction between ICs of a device. The number of interconnect levels for circuitry has substantially increased due to the large number of devices that are now interconnected in a state-of-the-art mobile application device.

These interconnections include back-end-of-line (BEOL) interconnect layers, which may refer to the conductive interconnect layers for electrically coupling to front-end-of-line (FEOL) active devices of an IC. The various BEOL interconnect layers are formed at corresponding BEOL interconnect levels, in which lower BEOL interconnect levels generally use thinner metal layers relative to upper BEOL interconnect levels. The BEOL interconnect layers may electrically couple to middle-of-line (MOL) interconnect layers, which interconnect to the FEOL active devices of an IC.

As used herein, the term “layer” includes a film, and is not construed as indicating a vertical or horizontal thickness unless otherwise stated. As used herein, the term “chiplet” may refer to an integrated circuit block, a functional circuit block, or other like circuit block specifically designed to work with one or more other chiplets to form a larger, more complex chiplet architecture.

State-of-the-art mobile application devices demand a small form factor, low cost, a tight power budget, and high electrical performance. Mobile package design has evolved to meet these divergent goals for enabling mobile applications that support multimedia enhancements. For example, a mobile application device can include multiple antenna modules and a system-on-chip (SoC) that includes one or more processors. These mobile application devices, however, are susceptible to overheating issues when multiple heat sources (e.g., the antenna modules and SoC) are arranged within the small form factor.

Aspects of the present disclosure are directed to a mold compound embedded device cooling structure. A packaged integrated circuit device includes a semiconductor die and a sealed two-phase cooling structure thermally coupled to the semiconductor die. The packaged integrated circuit device also includes a mold compound encapsulating the semiconductor die and the sealed two-phase cooling structure. The disclosed packaged integrated circuit device with the mold compound embedded device cooling structure provides improved thermal distribution.

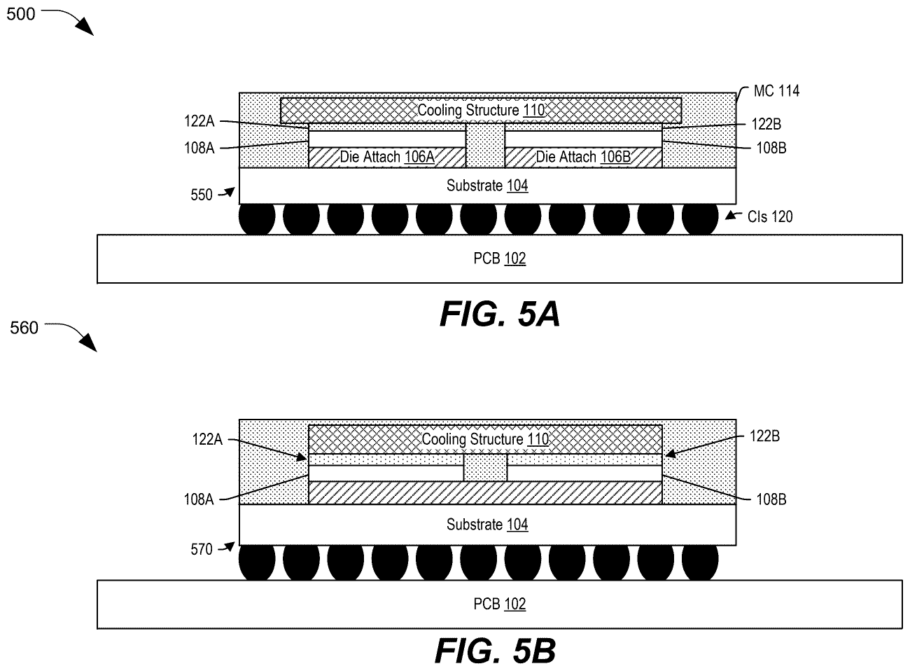

In some drawings, multiple instances of a particular type of feature are used. Although these features are physically and/or logically distinct, the same reference number is used for each, and the different instances are distinguished by addition of a letter to the reference number. When the features as a group or a type are referred to herein e.g., when no particular one of the features is being referenced, the reference number is used without a distinguishing letter. However, when one particular feature of multiple features of the same type is referred to herein, the reference number is used with the distinguishing letter. For example, referring to FIG. 5A, multiple dies are illustrated and associated with reference numbers 108A and 108B. When referring to a particular one of these dies, such as a die 108A, the distinguishing letter “A” is used. However, when referring to any arbitrary one of these dies or to these dies as a group, the reference number 108 is used without a distinguishing letter.

### Exemplary Implementations Including Mold Compound Embedded Device Cooling Structures

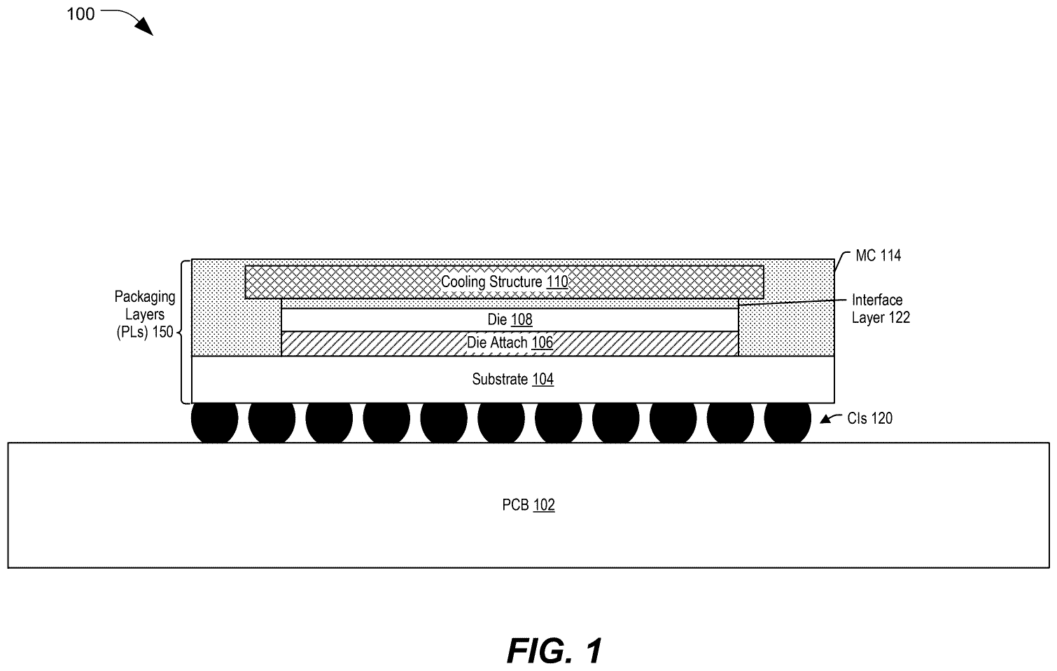

FIG. 1 illustrates a cross-sectional profile view of an exemplary device 100 that includes a mold compound embedded device cooling structure. In the implementation shown in FIG. 1, the device 100 includes packaging layers (PLs) 150 electrically connected via conductive interconnects (CIs) 120 to a printed circuit board (PCB) 102.

The packaging layers 150 include a die 108 (e.g., a semiconductor die) electrically connected via a die attach 106 to a first surface (e.g., a top surface) of a substrate 104. The CIs 120 are electrically connected to a second surface (e.g., a bottom surface) of the substrate 104 that is opposite to the first surface. In a particular aspect, the die 108 includes one or more processors, a system-on-chip (SoC) including one or more processors, a central processing unit (CPU), a graphics processing unit (GPU), an audio processor, a video processor, a display, or a combination thereof. The substrate 104 is attached (e.g., via the CIs 120) to the PCB 102.

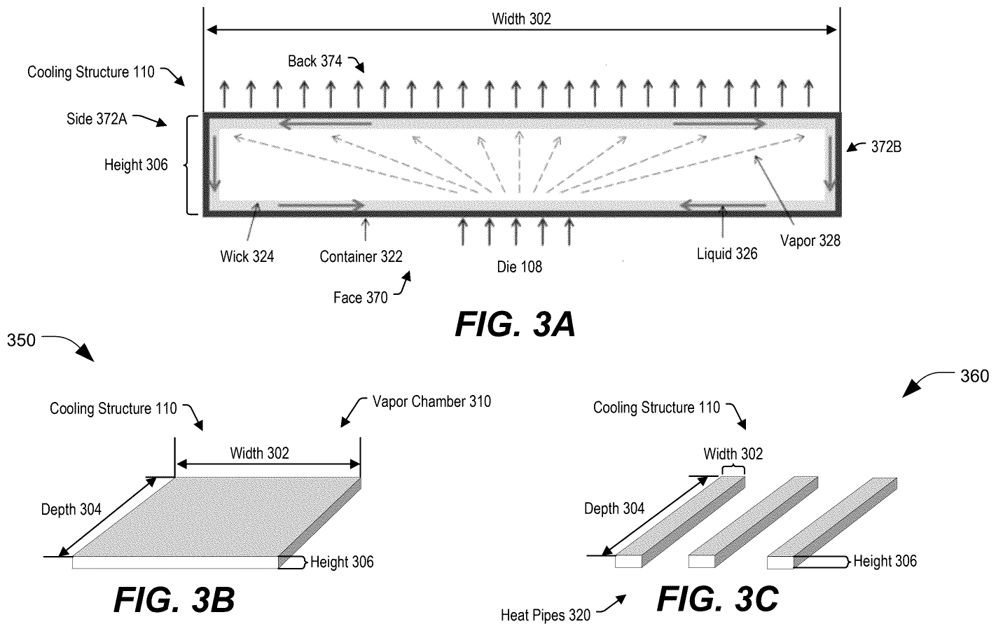

The packaging layers 150 include a mold compound (MC) 114 formed on the substrate 104. The die 108 and the die attach 106 are at least partially encapsulated in the mold compound 114. A cooling structure 110 is encapsulated (e.g., embedded) in the mold compound 114. In a particular aspect, the cooling structure 110 includes a sealed two-phase cooling structure, as further described with reference to FIG. 3. For example, the cooling structure 110 includes a vapor chamber, one or more heat pipes, or a combination thereof. The cooling structure 110 is thermally coupled to the die 108. In a particular aspect, the die 108 is between the cooling structure 110 and the substrate 104.

A first surface (e.g., a face) of the cooling structure 110 is adjacent to and aligned with a second surface (e.g., a face) of the die 108. The first surface has a first surface area and the second surface has a second surface area. In some implementations, the first surface area is larger than (e.g., greater than) the second surface area. In the example illustrated in FIG. 1, the cooling structure 110 extends (e.g., horizontally in the view shown in FIG. 1) past the edges of the die 108.

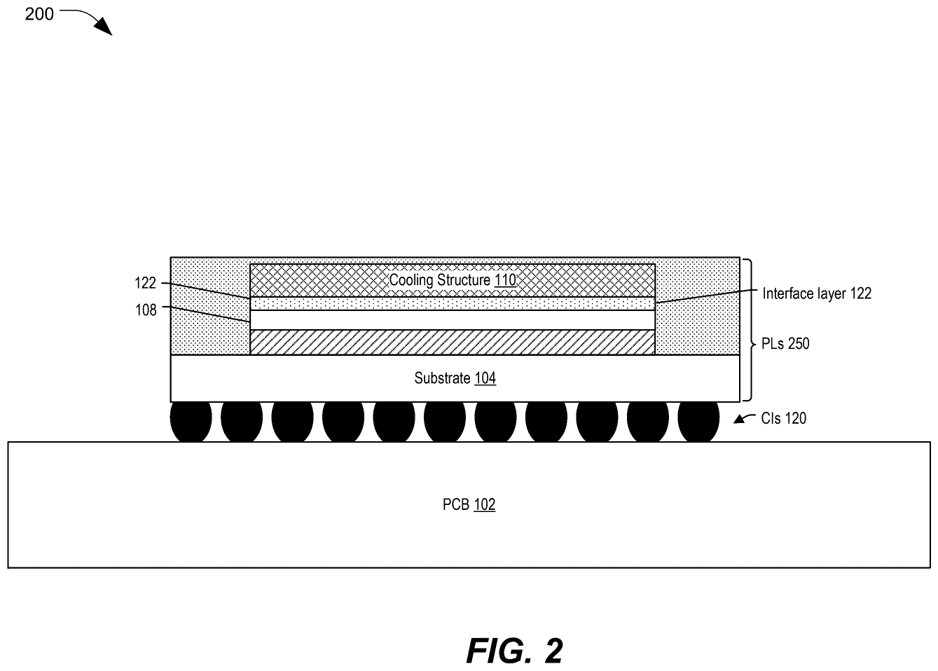

In some examples, the cooling structure 110 extends (e.g., horizontally in the view shown in FIG. 1) past one or more edges of the die 108. The first surface area may be less than, equal to, or greater than the second surface area. In yet other examples, the cooling structure does not extend (e.g., horizontally in the view shown in FIG. 2) past any edges of the die 108. To illustrate, the first surface area is less than or equal to the second surface area.

The packaging layers 150 include an interface layer 122 (e.g., a thermal interface layer) between the cooling structure 110 and the die 108. In the example of FIG. 1, the interface layer 122 includes a layer of the mold compound 114. In another example, the interface layer 122 includes another type of thermal interface layer, such as an adhesive layer (e.g., an epoxy), as further described with reference to FIG. 2. In a particular aspect, the interface layer 122 includes silicone, graphite, aluminum, boron nitride, aluminum oxide, acrylic, indium alloy, silver, copper, zinc oxide, silicon carbide, graphite, graphene, carbon nanotubes, polyurethane, metal, ceramic, polymer, elastomer, epoxy, adhesive, thermal interface material, a mold compound layer, or a combination thereof. In a particular aspect, the packaging layers 150 are enclosed in a shielding can. For example, the shielding can isolates the die 108 by creating a Faraday cage directly on the PCB 102.

In a particular implementation, the die 108 includes silicon, silicon carbide, gallium arsenide, or a combination thereof. In a particular aspect, the die attach 106 includes gold-tin, gold-silicon, a silver-filled glass compound, a silver-filled epoxy resin, or a combination thereof. In a particular aspect, the die attach 106 includes microbumps. In a particular implementation, one or more of the CIs 120 include tin, silver, copper, or a combination thereof. In a particular aspect, the mold compound 114 includes epoxy, plastic, polymer, silica, glass, or a combination thereof.

It should be understood that the device 100 may include additional components, other components, fewer components, or a combination thereof, to support the functionality described herein. As non-limiting examples, the device 100 may include additional IC devices, additional layers, additional dies, additional cooling structures, additional packages, additional interconnects, additional structures, other components, different components, or a combination thereof, to support the functionality and technical advantages disclosed herein.

During operation of the device 100, when the die 108 produces heat, working fluid in an evaporator portion of the cooling structure 110 that is closer to the die 108 undergoes a phase change from liquid to vapor. As the working fluid (as vapor) spreads away from the die 108 and enters a condenser portion of the cooling structure 110, the working fluid condenses back to a liquid and flows back to the evaporator portion of the cooling structure 110. In some examples, a heat sink or condenser above (in the view shown in FIG. 3A) the condenser portion of the cooling structure 110 cools the condenser portion to cause the working fluid to condense back to a liquid.

The die 108 can include integrated circuitry, such as a plurality of transistors and/or other circuit elements arranged and interconnected to form logic cells, memory cells, etc. Components of the integrated circuitry can be formed in and/or over a semiconductor substrate (e.g., the substrate 104). Different implementations can use different types of transistors, such as a field effect transistor (FET), planar FET, finFET, a gate all around FET, or mixtures of transistor types. In some implementations, a front end-of-line (FEOL) process may be used to fabricate the integrated circuitry in and/or over the semiconductor substrate.

The die 108 may include or correspond to particular IC devices that can be arranged and interconnected as a three-dimensional (3D) IC device. In some implementations, the die 108 includes one or more microcontrollers, application specific integrated circuits (ASICs), field programmable gate arrays (FPGAs), central processing units (CPUs) having one or more processing cores, processing systems, system on chip (SoC), or other circuitry and logic configured to facilitate the operations of the die 108. Additionally, or alternatively, the dies 108 may include or operate as a memory, such as a static random-access memory (SRAM), a dynamic random-access memory (DRAM), flash memory, read-only memory (ROM), programmable read-only memory (PROM), erasable programmable read-only memory (EPROM), electrically erasable programmable read-only memory (EEPROM), a solid-state storage device (SSD), or a combination thereof.

In some implementations, IC dies are electrically connected to, or integrated with, respective substrates. For example, the die 108 may be electrically connected (e.g., via one or more contacts or interconnects) to the substrate 104. In some implementations, the packaging layers 150, including the die 108, are electrically connected via the CIs 120 to the PCB 102. Any of the conductive interconnects and contacts described herein can include, for example, microbumps, conductive pillars, conductive pads (e.g., for pad to pad bonding), or other similar chiplet-to-chiplet interconnect contacts used for three-dimensional (3D) chiplet stacking.

The device 100 thus experiences improved thermal distribution as compared to other devices that do not include the cooling structure 110 embedded within the mold compound 114. A technical advantage of the cooling structure 110 embedded in the mold compound 114 includes improved performance of the die 108, reduced heat generation of the device 100, or both.

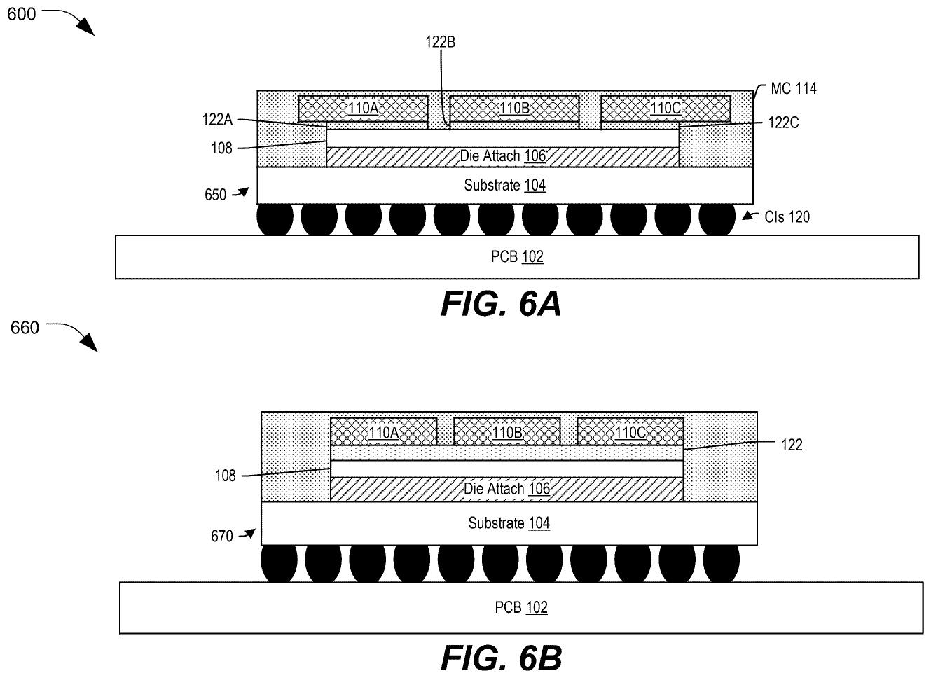

In a particular implementation, the device 100 includes multiple dies 108 encapsulated in the mold compound 114 and a single cooling structure (e.g., the cooling structure 110) is thermally coupled to the multiple dies 108, as further described with reference to FIGS. 5A and 5B. In a particular implementation, the device 100 includes multiple cooling structures 110 encapsulated in the mold compound 114 and the multiple cooling structures 110 are thermally coupled to a single die (e.g., the die 108), as further described with reference to FIGS. 6A and 6B. In some examples, at least one of the multiple cooling structures 110 includes a vapor chamber and at least one of the multiple cooling structures 110 includes one or more heat pipes.

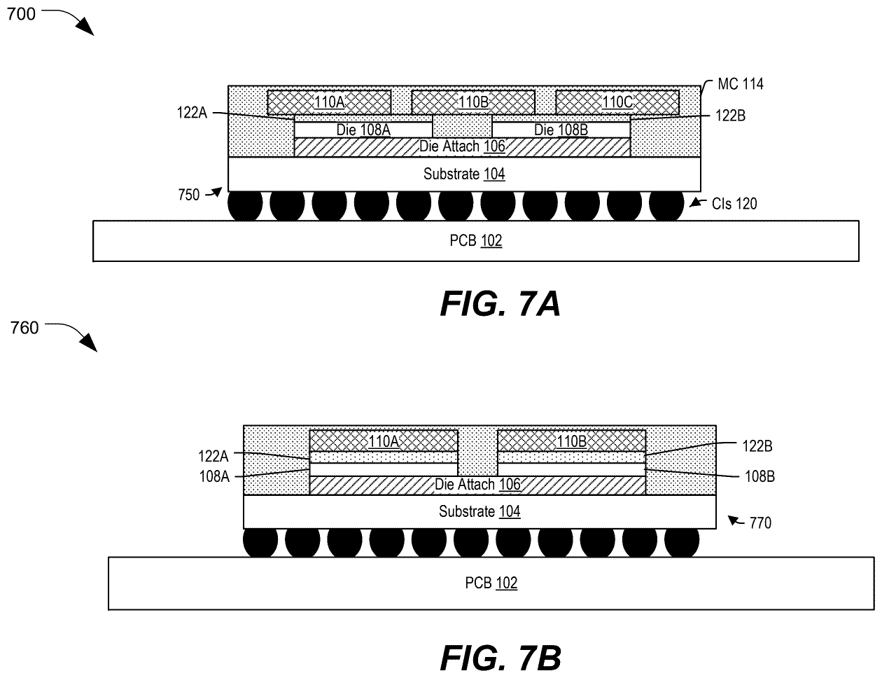

In a particular implementation, the device 100 includes multiple dies 108 and multiple cooling structures 110 encapsulated in the mold compound 114, as further described with reference to FIGS. 7A and 7B. In this implementation, a first die 108 is thermally coupled to a first cooling structure 110 and a second die 108 is thermally coupled to a second cooling structure 110. In some examples, the first cooling structure 110 includes a vapor chamber and the second cooling structure 110 includes one or more heat pipes.

FIG. 2 illustrates a cross-sectional profile view of a particular implementation of a device 200 that includes a mold compound embedded device cooling structure (e.g., the cooling structure 110). The device 200 of FIG. 2 includes many of the same components and features as are described above with reference to FIG. 1. Such components and features are physically and operationally the same as described above with reference to FIG. 1 and are labeled in FIG. 2 using the same reference numbers.

In the example shown in FIG. 2, the device 200 includes PLs 250 attached via the CIs 120 to the PCB 102. The PLs 250 include the interface layer 122 (e.g., a thermal interface layer, such as an epoxy) between the cooling structure 110 and the die 108.

A first surface (e.g., a face) of the cooling structure 110 is adjacent to and aligned with a second surface (e.g., a face) of the die 108. The first surface has a first surface area and the second surface has a second surface area. In the example illustrated in FIG. 2, the first surface area is at least as large as the second surface area. In some other examples, the first surface area can be less than the second surface area.

FIG. 3A illustrates a cross-sectional profile view of a particular implementation of the cooling structure 110 of the device 100 of FIG. 1, the device 200 of FIG. 2, or both. FIG. 3B illustrates an example 350 of a particular implementation of the cooling structure 110 as a vapor chamber 310. FIG. 3C illustrates an example 360 of a particular implementation of the cooling structure 110 as a heat pipe 320. In some implementations, the device 100 of FIG. 1, the device 200 of FIG. 2, or both, include multiple heat pipes 320 as the cooling structure 110.

In a particular aspect, the cooling structure 110 corresponds to a rectangular container 322. For example, the cooling structure 110 has a face 370, a back 374, and two sides 372 (e.g., a side 372A and a side 372B) defining a space therebetween. The face 370 is opposite to the back 374 and the side 372A is opposite to the side 372B. In a particular aspect, a surface area of the face 370 is greater than a surface area of each of the sides 372 and is the same as a surface area of the back 374. In a particular aspect, each of the sides 372 has a height 306 and each of the face 370 and the back 374 has a width 302. The vapor chamber 310 has a depth 304. In a particular aspect, the height 306 is less than each of the width 302 and the depth 304. In a particular aspect, the cooling structure 110 corresponds to a hollow tube, such as a heat pipe 320, or a hollow chamber, such as a vapor chamber 310. In a particular aspect, the container 322 is sealed.

In a particular aspect, the cooling structure 110 is made of conductive materials (e.g., copper, aluminum, or both). According to some implementations, a wicking structure 324 is formed on the inside of the container 322. According to some implementations, a grain size of the wicking structure 324 is greater than or equal to 8 microns and less than or equal to 12 microns. In a particular example, a characteristic grain size of the wicking structure is approximately equal to 10 microns.

A working fluid is added in a volume defined by the cooling structure 110. In some implementations, the working fluid includes water, distilled water, acetone, one or more additives, or a combination thereof. The working fluid has greater than threshold thermal conductivity (e.g., greater than or equal to 0.6 watts per meter-kelvin at room temperature (25 degrees Celsius)) and lower than threshold boiling point (e.g., less than or equal to 100 degrees Celsius). In some implementations, an operating pressure of the cooling structure 110 may be set to achieve a lower boiling point (e.g., less than or equal to room temperature).

In an example, the cooling structure 110 is in thermal communication with a heat source (e.g., one or more dies 108) coupled to (e.g., proximate to) the cooling structure 110. In a particular aspect, the heat source (e.g., one or more dies 108) includes one or more processors, a SoC including one or more processors, a CPU, a GPU, an audio processor, a video processor, a display, or a combination thereof. When the heat source (e.g., a die 108) produces heat, the inside the cooling structure 110 warms up and the working fluid undergoes a phase change from liquid 326 to vapor 328 at a relatively low temperature. According to some implementations, the cooling structure 110 includes one or more evaporator portions where heat from the heat source (e.g., the die 108) is applied to the working fluid and the working fluid undergoes the phase change from liquid 326 to vapor 328.

As the working fluid (e.g., as vapor 328) spreads away from the heat source, the working fluid passes from the one or more evaporator portions to one or more cooler condenser portions of the cooling structure 110 and condenses to a liquid phase. According to some implementations, the cooling structure 110 is in thermal communication with one or more heatsinks. The one or more heatsinks include an ambient environment, a heat spreader, or both. A region (e.g., the condenser portions) of the cooling structure 110, cooled by a heatsink, causes the working fluid in the region to condense. The working fluid (e.g., as liquid 326) flows back via the wicking structure 324 (e.g., via capillary action) to the one or more evaporator portions of the cooling structure 110. In a particular aspect, the one or more evaporator portions are closer to the back 374, and the one or more condenser portions are closer to the face 370 of the cooling structure 110.

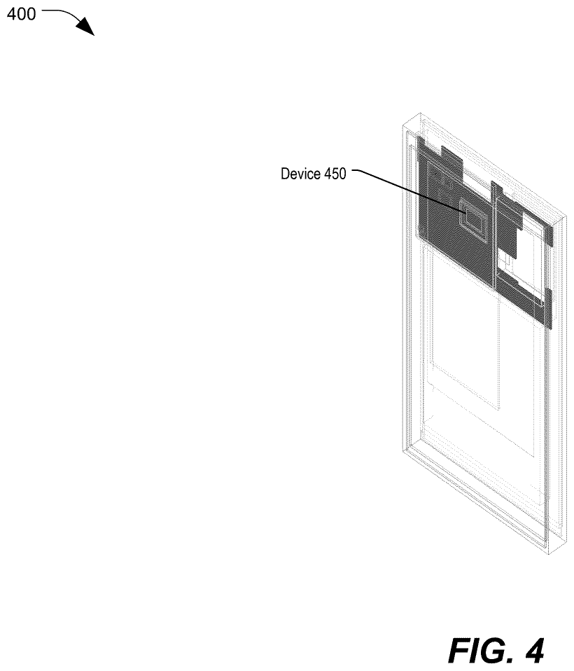

FIG. 4 illustrates a device 450 integrated in a mobile device 400. The device 450 may include the device 100 of FIG. 1, the device 200 of FIG. 2, or both. In some implementations, the device 450 can be integrated in a smartphone, a tablet computer, a fixed location terminal device, an automobile, a wearable electronic device, a laptop computer, or some combination thereof, as described in more detail below with reference to FIG. 16. As described with reference to FIGS. 1-3, the device 450 includes the mold compound embedded cooling structure 110 to provide improved thermal distribution for the mobile device 400. A technical advantage of the cooling structure 110 is to improve performance, reduce die temperature, or both.

FIG. 5A illustrates a cross-sectional profile view of a particular implementation of a device 500 that includes a single mold compound embedded device cooling structure (e.g., the cooling structure 110) thermally coupled to multiple dies. For example, the cooling structure 110 is thermally coupled to a die 108A and a die 108B.

The device 500 of FIG. 5A includes many of the same components and features as are described above with reference to FIG. 1. Such components and features are physically and operationally the same as described above with reference to FIG. 1 and are labeled in FIG. 5A using the same reference numbers.

The device 500 includes PLs 550 attached via the CIs 120 to the PCB 102. A plurality of dies 108, such as a die 108A and a die 108B, are at least partially embedded in the mold compound 114 of the PLs 550. An interface layer 122 is formed between the cooling structure 110 and each of the multiple dies 108. For example, an interface layer 122A (e.g., a layer of the mold compound 114) is formed between the cooling structure 110 and the die 108A. As another example, an interface layer 122B (e.g., a layer of the mold compound 114) is formed between the cooling structure 110 and the die 108B. The cooling structure 110 thermally coupled to two dies 108 is provided as an illustrative example, in other examples the cooling structure 110 can be coupled to fewer than two dies 108 or more than two dies 108.

FIG. 5B illustrates a cross-sectional profile view of a particular implementation of a device 560 that includes a single mold compound embedded device cooling structure (e.g., the cooling structure 110) thermally coupled to multiple dies. For example, the cooling structure 110 is thermally coupled to the die 108A and the die 108B.

The device 560 of FIG. 5B includes many of the same components and features as are described above with reference to FIG. 5A. Such components and features are physically and operationally the same as described above with reference to FIG. 5A and are labeled in FIG. 5B using the same reference numbers.

The device 560 includes PLs 570 attached via the CIs 120 to the PCB 102. The interface layer 122 of the PLs 570 includes a thermal interface layer (e.g., an epoxy layer) between the cooling structure 110 and each of the multiple dies 108. For example, an interface layer 122A is formed between the cooling structure 110 and the die 108A. As another example, an interface layer 122B is formed between the cooling structure 110 and the die 108B. The cooling structure 110 thermally coupled to two dies 108 is provided as an illustrative example, in other examples the cooling structure 110 can be coupled to fewer than two dies 108 or more than two dies 108.

FIG. 6A illustrates a cross-sectional profile view of a particular implementation of a device 600 that includes multiple mold compound embedded device cooling structures thermally coupled to a single die (e.g., the die 108). For example, the die 108 is thermally coupled to a cooling structure 110A, a cooling structure 110B, and a cooling structure 110C.

The device 600 of FIG. 6A includes many of the same components and features as are described above with reference to FIG. 1. Such components and features are physically and operationally the same as described above with reference to FIG. 1 and are labeled in FIG. 6A using the same reference numbers.

The device 600 includes PLs 650 attached via the CIs 120 to the PCB 102. A plurality of cooling structures 110, such as a cooling structure 110A, a cooling structure 110B, and a cooling structure 110C, are embedded in the mold compound 114 of the PLs 650. An interface layer 122 is formed between each of the cooling structures 110 and the die 108. For example, an interface layer 122A (e.g., a layer of the mold compound 114) is formed between the die 108 and the cooling structure 110A. As another example, an interface layer 122B (e.g., a layer of the mold compound 114) is formed between the die 108 and the cooling structure 110B. As yet another example, an interface layer 122C (e.g., a layer of the mold compound 114) is formed between the die 108 and the cooling structure 110C.The die 108 thermally coupled to three cooling structures 110 is provided as an illustrative example, in other examples the die 108 can be coupled to fewer than three cooling structures 110 or more than three cooling structures 110.

FIG. 6B illustrates a cross-sectional profile view of a particular implementation of a device 660 that includes multiple mold compound embedded device cooling structures thermally coupled to a single die (e.g., the die 108). For example, the die 108 is thermally coupled to the cooling structure 110A, the cooling structure 110B, and the cooling structure 110C.

The device 660 of FIG. 6B includes many of the same components and features as are described above with reference to FIG. 6A. Such components and features are physically and operationally the same as described above with reference to FIG. 6A and are labeled in FIG. 6B using the same reference numbers.

The device 660 includes PLs 670 attached via the CIs 120 to the PCB 102. The interface layer 122 of the PLs 670 includes a thermal interface layer (e.g., an epoxy layer) between each of the cooling structures 110 and the die 108. For example, each of the cooling structure 110A, the cooling structure 110B, and the cooling structure 110C is formed on an interface layer 122 that is formed on the die 108.

The die 108 thermally coupled to three cooling structures 110 is provided as an illustrative example, in other examples the die 108 can be coupled to fewer than three cooling structures 110 or more than three cooling structures 110.

FIG. 7A illustrates a cross-sectional profile view of a particular implementation of a device 700 that includes multiple mold compound embedded device cooling structures thermally coupled to multiple dies. For example, a die 108A is thermally coupled to a cooling structure 110A and a cooling structure 110B. As another example, a die 108B is thermally coupled to the cooling structure 110B and a cooling structure 110C.

The device 700 of FIG. 7A includes many of the same components and features as are described above with reference to FIG. 1. Such components and features are physically and operationally the same as described above with reference to FIG. 1 and are labeled in FIG. 7A using the same reference numbers.

The device 700 includes PLs 750 attached via the CIs 120 to the PCB 102. A plurality of cooling structures 110, such as a cooling structure 110A, a cooling structure 110B, and a cooling structure 110C, are embedded in the mold compound 114 of the PLs 650. A plurality of dies 108, such as a die 108A and a die 108B, are at least partially embedded in the mold compound 114. An interface layer 122 is formed between each of the dies 108 and one or more of the cooling structures 110. For example, an interface layer 122A (e.g., a layer of the mold compound 114) is formed between the die 108A and each of the cooling structure 110A and the cooling structure 110B. As another example, an interface layer 122B (e.g., a layer of the mold compound 114) is formed between the die 108B and each of the cooling structure 110B and the cooling structure 110C. Two dies 108 thermally coupled to three cooling structures 110 is provided as an illustrative example, in other examples fewer than two dies 108 or more than two dies 108 can be thermally coupled to fewer than three cooling structures 110 or more than three cooling structures 110.

FIG. 7B illustrates a cross-sectional profile view of a particular implementation of a device 760 that includes multiple mold compound embedded device cooling structures thermally coupled to multiple dies. For example, a die 108A is thermally coupled to a cooling structure 110A. As another example, a die 108B is thermally coupled to a cooling structure 110B.

The device 760 of FIG. 7B includes many of the same components and features as are described above with reference to FIG. 7A. Such components and features are physically and operationally the same as described above with reference to FIG. 7A and are labeled in FIG. 7B using the same reference numbers.

The device 760 includes PLs 770 attached via the CIs 120 to the PCB 102. The interface layer 122 of the PLs 770 includes a thermal interface layer (e.g., an epoxy layer) between each of the dies 108 and a corresponding one of the cooling structures 110. For example, an interface layer 122A is formed between the die 108A and the cooling structure 110A. As another example, an interface layer 122B is formed between the die 108B and the cooling structure 110B. Two dies 108 thermally coupled to two cooling structures 110 is provided as an illustrative example, in other examples fewer than two dies 108 or more than two dies 108 can be thermally coupled to fewer than two cooling structures 110 or more than two cooling structures 110.

The example devices of FIGS. 1-7B can be integrated with or included within a wide variety of other devices. For example, a device that includes one or more of the mold compound embedded device cooling structures disclosed herein can include components such as a power management integrated circuit (PMIC), an application processor, a modem, a radio frequency (RF) device, a passive device, a filter, a capacitor, an inductor, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. In such devices, the device 100, 200, 500, 560, 600, 660, 700, or 760 can operate as any of these components (or a combination of these components) that includes active circuitry.

### Exemplary Sequences for Fabricating a Device/IC Device Including Mold Compound Embedded Device Cooling Structure

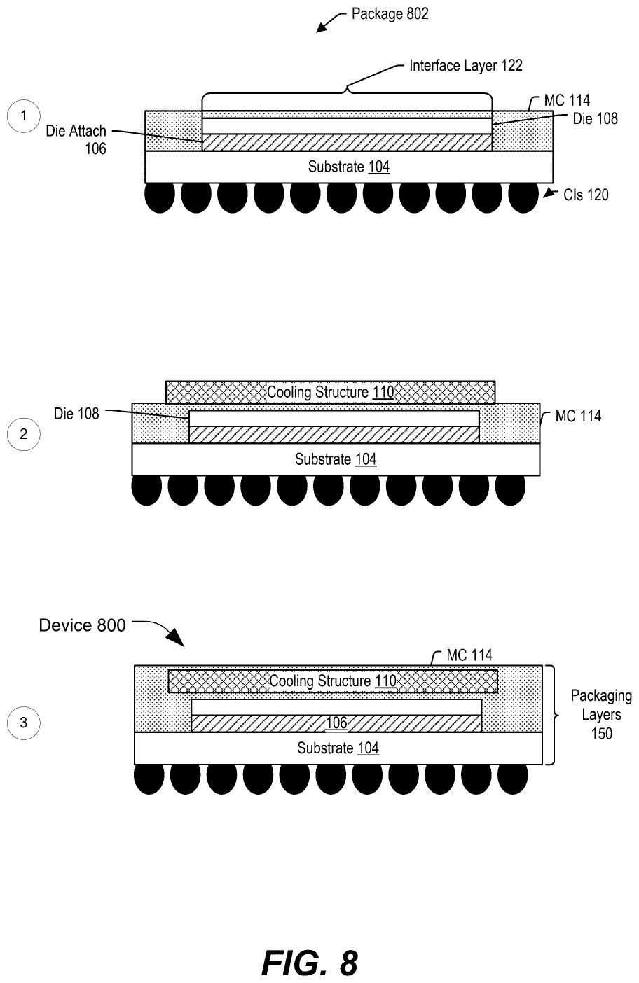

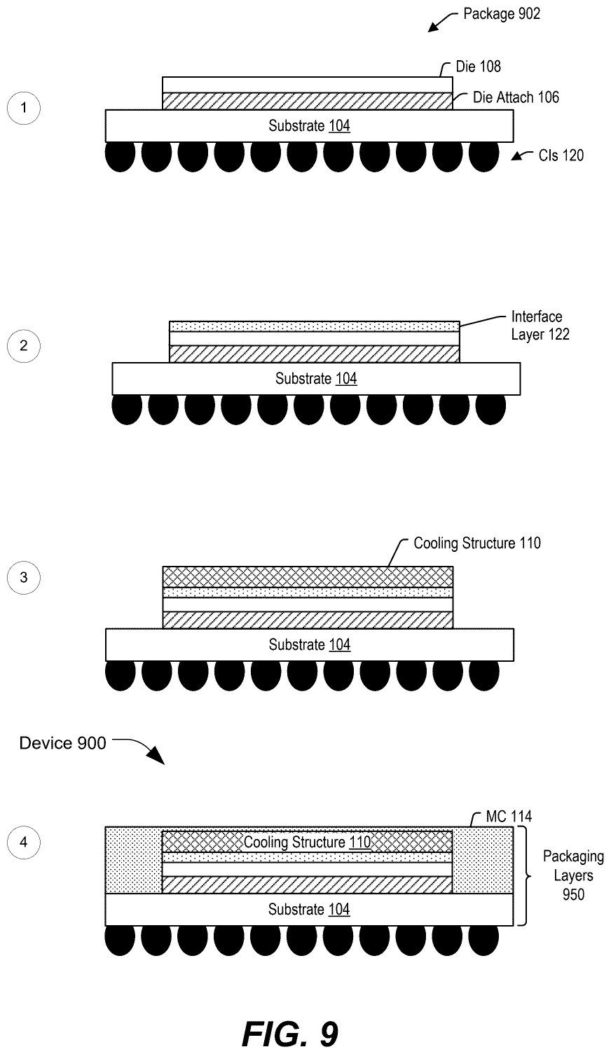

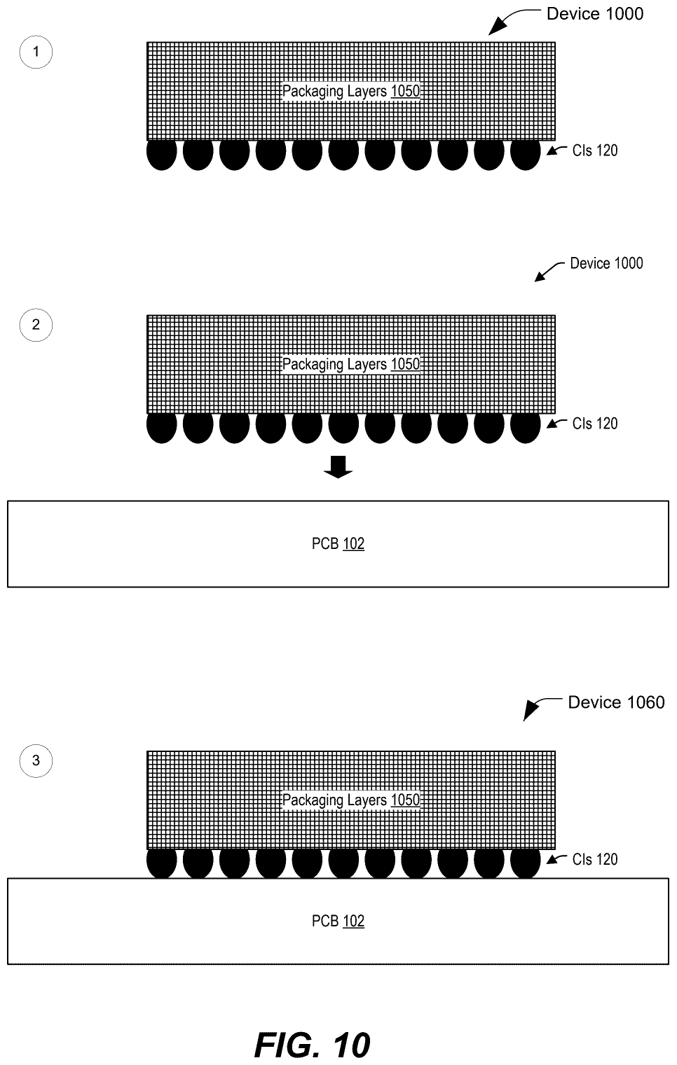

In some implementations, fabricating a device including a mold compound embedded device cooling structure (e.g., any of the devices 100, 200, 500, 560, 600, 660, 700, or 760) includes several processes. FIG. 8 illustrates an exemplary sequence for fabricating or providing a device that includes a mold compound embedded device cooling structure, as described with reference to FIG. 1. FIG. 9 illustrates an exemplary sequence for fabricating or providing a device that includes a mold compound embedded device cooling structure, as described with reference to FIG. 2. FIG. 10 illustrates an exemplary sequence for fabricating or providing a device that includes a mold compound embedded device cooling structure, as described with reference to FIGS. 1 and 2. In some implementations, the sequence of FIGS. 8, 10, and 11 may be used to provide (e.g., during fabrication of) the device 100 of FIG. 1. In some implementations, the sequence of FIGS. 9-11 may be used to provide (e.g., during fabrication of) the device 200 of FIG. 2.

It should be noted that the sequences of FIGS. 8-11 may combine one or more stages in order to simplify and/or clarify the sequence for providing or fabricating an integrated device. In some implementations, the order of the processes may be changed or modified. In some implementations, one or more of the processes may be replaced or substituted without departing from the scope of the disclosure. In the following description, reference is made to various illustrative Stages of the sequences, which are numbered (using circled numbers) in FIGS. 8-11. Each of the various stages of the sequence illustrated in FIGS. 8-11 shows one or more integrated devices being formed. In other implementations, a single integrated device may be formed or a plurality of integrated devices can be formed concurrently.

Stage 1 of FIG. 8 illustrates a state after obtaining a package 802. The package 802 includes the die 108 attached via the die attach 106 to a first surface of the substrate 104. The CIs 120 are attached to a second surface of the substrate 104. The die 108 and the die attach 106 at least partially encapsulated in the MC 114. A layer of the MC 114 that is on the die 108 corresponds to the interface layer 122. In some implementations, a thinning process is applied to the MC 114 to achieve a target thickness of the interface layer 122. In a particular aspect, the thinning process includes at least one of chemical mechanical planarization (CMP), plasma etching, laser ablation, mechanical grinding, chemical etching, polishing, thermal reflow, or a combination thereof.

Stage 2 illustrates a state after attaching a cooling structure 110 on a surface of the mold compound 114. For example, as part of Stage 2, the cooling structure 110 is positioned to at least partially align with the interface layer 122. In a particular aspect, an adhesive material is applied to the surface of the mold compound 114 prior to placing the cooling structure 110 on the adhesive material. In some implementations, if the adhesive material includes a thermal adhesive, a curing process is applied to attach the cooling structure 110 to the mold compound 114.

Stage 3 illustrates a state after applying the mold compound 114 to encapsulate the cooling structure 110. For example, as part of Stage 3, the mold compound 114 is applied as a liquid or paste, and subsequently cured (e.g., by exposure to heat, a chemical curing agent, light, etc.) to encapsulate the cooling structure 110. The mold compound 114 solidifies with the cooling structure 110 embedded in the mold compound 114.

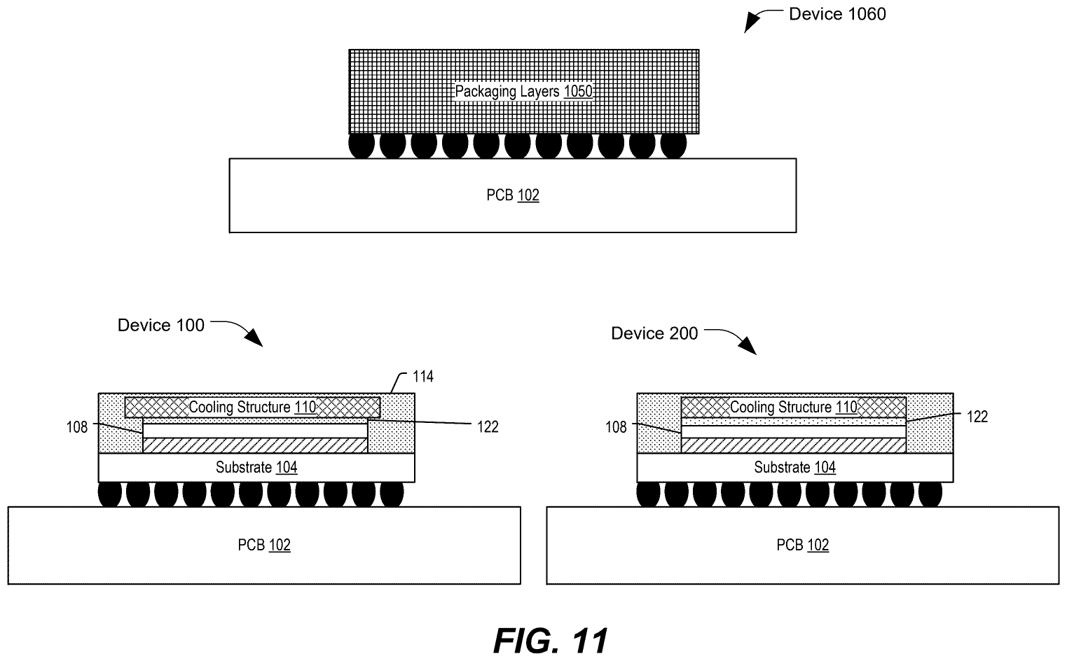

Formation of a device 800 (e.g., a device including a mold embedded device cooling structure) is complete after Stage 3 of FIG. 8. The device 800 can be used to form the device 100 of FIG. 1, as further described with reference to FIGS. 10-11.

Although certain Stages are illustrated in FIG. 8 in forming the device 800, other processes can be included in the fabrication of the device 800 without departing from the scope of the subject disclosure. For example, fabricating the device 800 can include obtaining the package 802 with multiple dies, such as a die 108A and a die 108B attached to the substrate 104 and encapsulated in the mold compound 114, attaching the cooling structure 110 to a surface of the mold compound 114 such that the cooling structure 110 is at least partially aligned with the multiple dies 108, and encapsulating the cooling structure 110 in the mold compound 114. In this example, the device 800 can be used to form the device 500 of FIG. 5A, as further described with reference to FIGS. 10-11.

Additionally, or alternatively, fabricating the device 800 can include, after obtaining the package 802 in Stage 1 of FIG. 8, attaching multiple cooling structures 110 to a surface of the mold compound 114 such that each of the cooling structures 110 is at least partially aligned with the die 108, and encapsulating the cooling structures 110 in the mold compound 114. In this example, the device 800 can be used to form the device 600 of FIG. 6A, as further described with reference to FIGS. 10-11.

Additionally, or alternatively, fabricating the device 800 can include obtaining the package 802 with multiple dies, such as a die 108A and a die 108B attached to the substrate 104 and encapsulated in the mold compound 114, attaching multiple cooling structures 110 to a surface of the mold compound 114 such that each of the cooling structures 110 is at least partially aligned with at least one of the multiple dies 108, and encapsulating the cooling structures 110 in the mold compound 114. In this example, the device 800 can be used to form the device 700 of FIG. 7A, as further described with reference to FIGS. 10-11.

Stage 1 of FIG. 9 illustrates a state after obtaining a package 902. The package 902 includes the die 108 attached via the die attach 106 to a first surface of the substrate 104. The CIs 120 are attached to a second surface of the substrate 104.

Stage 2 illustrates a state after applying a thermal interface layer (e.g., an epoxy layer) as an interface layer 122 to a surface of the die 108. For example, applying the interface layer 122 can include dispensing or coating the interface layer 122 (e.g., an epoxy layer) on the surface of the die 108 and using curing processes to cure the interface layer 122. In a particular aspect, curing processes can include oven curing, hot plate curing, or using a reflow oven. UV-curable epoxies are exposed to ultraviolet light for curing.

Stage 3 illustrates a state after attaching a cooling structure 110 on a surface of the interface layer 122. For example, as part of Stage 3, the cooling structure 110 is positioned to at least partially align with the interface layer 122. In some aspects, the interface layer 122 is cured after placing the cooling structure 110 on the interface layer 122.

Stage 4 illustrates a state after applying the mold compound 114 to encapsulate the cooling structure 110. For example, as part of Stage 3, the mold compound 114 is applied as a liquid or paste, and subsequently cured (e.g., by exposure to heat, a chemical curing agent, light, etc.) to encapsulate the cooling structure 110, the interface layer 122, the die 108, and the die attach 106. The mold compound 114 solidifies with the cooling structure 110, the interface layer 122, the die 108, and the die attach 106 embedded in the mold compound 114. Packaging layers 950 include the cooling structure 110, the interface layer 122, the die 108, and the die attach 106 embedded in the mold compound 114 and formed on the substrate 104.

Formation of a device 900 (e.g., a device including a mold embedded device cooling structure) is complete after Stage 4 of FIG. 9. The device 900 can be used to form the device 200 of FIG. 2, as further described with reference to FIGS. 10-11.

Although certain Stages are illustrated in FIG. 9 in forming the device 900, other processes can be included in the fabrication of the device 900 without departing from the scope of the subject disclosure. For example, fabricating the device 900 can include obtaining the package 902 with multiple dies, such as a die 108A and the die 108B attached to the substrate 104, applying interface layers to each of the multiple dies (e.g., an interface layer 122A to the die 108A and an interface layer 122B to the die 108B), filling the space between and outside the dies 108 and the interface layers 122 with the mold compound 114, attaching the cooling structure 110 to the interface layers 122, and encapsulating the cooling structure 110, the interface layers 122, the dies 108, and the die attach 106 in the mold compound 114. In some examples, the mold compound 114 may be thinned to expose a surface of the interface layers 122 prior to attaching the cooling structure 110 to the interface layers 122. In this example, the device 900 can be used to form the device 560 of FIG. 5B, as further described with reference to FIGS. 10-11.

Additionally, or alternatively, fabricating the device 900 can include, after applying the interface layer 122 to the die 108 in Stage 2 of FIG. 9, attaching multiple cooling structures 110 to a surface of the interface layer 122, and encapsulating the cooling structures 110, the interface layer 122, the die 108, and the die attach 106 in the mold compound 114. In this example, the device 900 can be used to form the device 660 of FIG. 6B, as further described with reference to FIGS. 10-11.

Additionally, or alternatively, fabricating the device 900 can include obtaining the package 902 with multiple dies, such as a die 108A and the die 108B attached to the substrate 104, applying interface layers to each of the multiple dies (e.g., an interface layer 122A to the die 108A and an interface layer 122B to the die 108B), attaching cooling structures to each of the interface layers (e.g., a cooling structure 110A to the interface layer 122A and a cooling structure 110B to the interface layer 122B), and encapsulating the cooling structures 110, the interface layers 122, the dies 108, and the die attach 106 in the mold compound 114. In this example, the device 900 can be used to form the device 760 of FIG. 7B, as further described with reference to FIGS. 10-11.

Stage 1 of FIG. 10 illustrates a state after obtaining a device 1000 that includes packaging layers 1050 electrically connected to CIs 120. In a particular aspect, the packaging layers 1050 correspond to the packaging layers 150 of FIG. 1, the packaging layers 250 of FIG. 2, the packaging layers 550 of FIG. 5A, the packaging layers 570 of FIG. 5B, the packaging layers 650 of FIG. 6A, the packaging layers 670 of FIG. 6B, the packaging layers 750 of FIG. 7A, or the packaging layers 770 of FIG. 7B.

Stage 2 illustrates a state after positioning the device 1000 over the PCB 102. For example, the packaging layers 1050 are aligned relative to the PCB 102.

Stage 3 illustrates a state after attaching the device 1000 to the PCB 102. For example, after the device 1000 is placed on the PCB 102, reflow soldering is used to attach the CIs 120 to the PCB 102.

Formation of a device 1060 (e.g., a device including a mold embedded device cooling structure) is complete after Stage 3 of FIG. 10. In some examples, the device 1060 corresponds to the device 100, 200, 400, 450, 500, 560, 600, 660, 700, or 760. To illustrate, in FIG. 11, an example is shown of the device 1060 corresponding to the device 100 and an example is shown of the device 1060 corresponding to the device 200.

### Exemplary Flow Diagram of a Method for Fabricating a Device/Integrated Device Including Mold Compound Embedded Device Cooling Structure

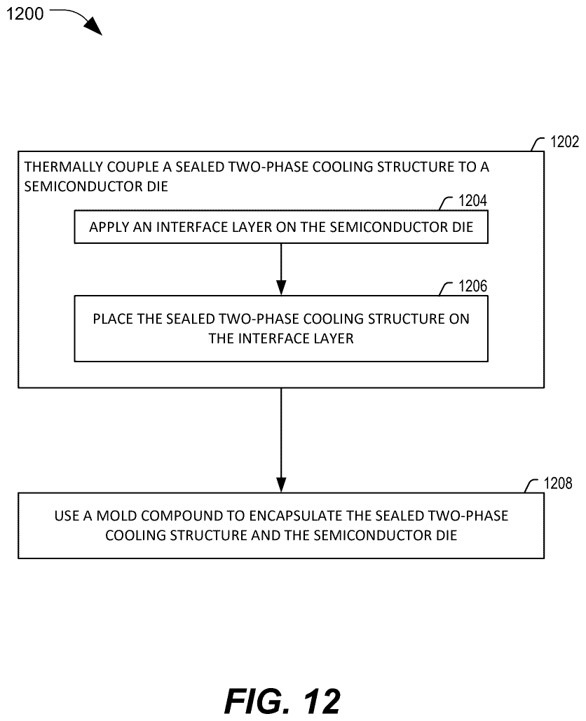

In some implementations, fabricating a device including mold compound embedded device cooling structure includes several processes. FIG. 12 illustrates an exemplary flow diagram of a method 1200 of fabricating an illustrative device that includes a mold compound embedded device cooling structure. In a particular aspect, one or more operations of the method 1200 are performed by one or more processors of a fabrication system. In some implementations, operations of the method 1200 may be stored as instructions by a non-transitory computer-readable storage medium, and the instructions may be executable by at least one processor to cause the at least one processor to perform operations of the method 1200. In some implementations, the method 1200 of FIG. 12 may be used to provide or fabricate any of the device 100 of FIG. 1, the device 200 of FIG. 2, the device 400 or the device 450 of FIG. 4, the device 500 of FIG. 5A, the device 560 of FIG. 5B, the device 600 of FIG. 6A, the device 660 of FIG. 6B, the device 700 of FIG. 7A, or the device 760 of FIG. 7B.

It should be noted that the method 1200 of FIG. 12 may combine one or more processes in order to simplify and/or clarify the method for providing or fabricating an integrated circuit device. In some implementations, the order of the processes may be changed or modified.

The method 1200 includes, at block 1202, thermally coupling a sealed two-phase cooling structure to a semiconductor die. In some implementations, the method 1200 includes, at block 1204, applying an interface layer on the semiconductor die. For example, Stage 1 of FIG. 8 illustrates and describes examples of applying a layer of the mold compound 114 on the die 108 as the interface layer 122. As another example, Stage 2 of FIG. 9 illustrates and describes examples of applying an interface layer 122 on the die 108 as the interface layer 122. In some implementations, the method 1200 also includes, at block 1206, placing the sealed two-phase cooling structure on the interface layer. For example, Stage 2 of FIG. 8 illustrates and describes examples of placing the cooling structure 110 on the layer of mold compound 114. As another example, Stage 3 of FIG. 9 illustrates and describes examples of placing the cooling structure 110 on the interface layer 122.

The method 1200 includes, at block 1208, using a mold compound to encapsulate the sealed two-phase cooling structure and the semiconductor die. For example, Stage 3 of FIG. 8 illustrates and describes examples of using the mold compound 114 to encapsulate the cooling structure 110 and the die 108. As another example, Stage 4 of FIG. 9 illustrates and describes examples of using the mold compound 114 to encapsulate the cooling structure 110 and the die 108.

### Exemplary Electronic Devices

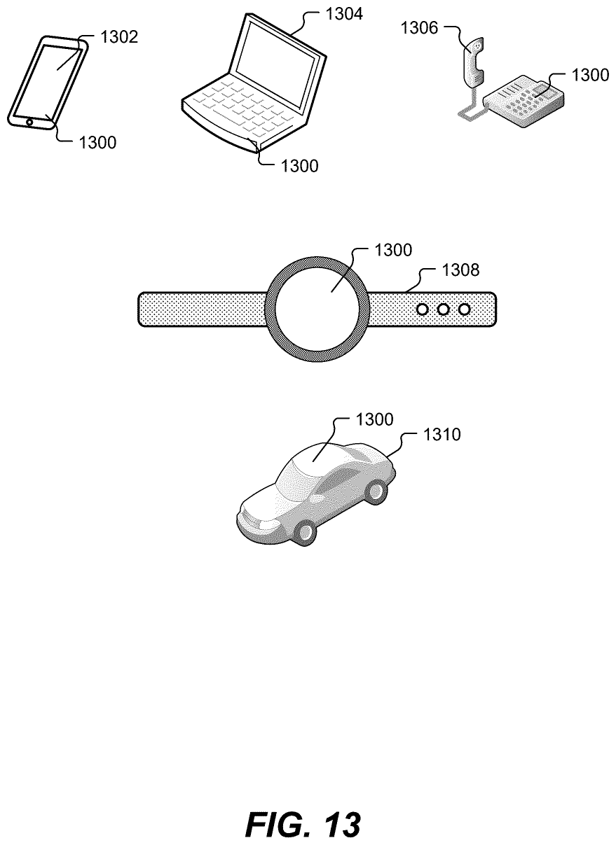

FIG. 13 illustrates various electronic devices that may include or be integrated with any of the device 100, 200, 450, 500, 560, 600, 660, 700, or 760 (that includes the mold compound embedded device cooling structure). For example, a mobile phone device 1302, a laptop computer device 1304, a fixed location terminal device 1306, a wearable device 1308, or a vehicle 1310 (e.g., an automobile or an aerial device) may include a device 1300. The device 1300 can include, for example, any of the device 100, 200, 450, 500, 560, 600, 660, 700, or 760, and/or any other integrated device that includes a mold compound embedded device cooling structure described herein. The devices 1302, 1304, 1306 and 1308 and the vehicle 1310 illustrated in FIG. 13 are merely exemplary. Other electronic devices may also feature the device 1300 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in vehicles (e.g., autonomous vehicles), or any other device that stores or retrieves data or computer instructions, or any combination thereof.

One or more of the components, processes, features, and/or functions illustrated in FIG. 1-13 may be rearranged and/or combined into a single component, process, feature or function or embodied in several components, processes, or functions. Additional elements, components, processes, and/or functions may also be added without departing from the disclosure. It should also be noted FIG. 1-13 and its corresponding description in the present disclosure is not limited to dies and/or ICs. In some implementations, FIG. 1-13 and its corresponding description may be used to manufacture, create, provide, and/or produce devices and/or integrated devices. In some implementations, a device may include a die, an integrated device, an embedded multi-chip package, an integrated passive device (IPD), a die package, an IC device, a device package, an IC package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first,” “second,” “third,” and “fourth” (and/or anything above fourth) is arbitrary. Any of the components described may be the first component, the second component, the third component or the fourth component. For example, a component that is referred to as a second component, may be the first component, the second component, the third component or the fourth component. The terms “encapsulate,” “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.
According to Example 1, a packaged integrated circuit device includes a semiconductor die; a sealed two-phase cooling structure thermally coupled to the semiconductor die; and a mold compound encapsulating the semiconductor die and the sealed two-phase cooling structure.
Example 2 includes the packaged integrated circuit device of Example 1, further comprising an interface layer between the sealed two-phase cooling structure and the semiconductor die.
Example 3 includes the packaged integrated circuit device of Example 1 or Example 2, wherein the interface layer includes a layer of mold compound.
Example 4 includes the packaged integrated circuit device of Example 2 or Example 3, wherein the interface layer includes a thermal interface material.
Example 5 includes the packaged integrated circuit device of any of Examples 1 to 4, wherein the sealed two-phase cooling structure extends past an edge of the semiconductor die.
Example 6 includes the packaged integrated circuit device of any of Examples 1 to 5, wherein a face of the sealed two-phase cooling structure is adjacent to and aligned with a face of the semiconductor die, and wherein the face of the sealed two-phase cooling structure is at least as large as the face of the semiconductor die.
Example 7 includes the packaged integrated circuit device of any of Examples 1 to 6, wherein the sealed two-phase cooling structure includes a vapor chamber.
Example 8 includes the packaged integrated circuit device of any of Examples 1 to 7, wherein the sealed two-phase cooling structure includes one or more heat pipes.
Example 9 includes the packaged integrated circuit device of any of Examples 1 to 8, and further includes a package substrate, the semiconductor die attached to the package substrate, wherein the semiconductor die is between the package substrate and the sealed two-phase cooling structure.
Example 10 includes the packaged integrated circuit device of any of Examples 1 to 9, and further includes a second semiconductor die, wherein the sealed two-phase cooling structure is thermally coupled to the second semiconductor die, and wherein the mold compound encapsulates the second semiconductor die.
Example 11 includes the packaged integrated circuit device of any of Examples 1 to 10, and further includes a second sealed two-phase cooling structure thermally coupled to the semiconductor die, wherein the mold compound encapsulates the second sealed two-phase cooling structure.
Example 12 includes the packaged integrated circuit device of Example 11, wherein the sealed two-phase cooling structure includes a vapor chamber and the second sealed two-phase cooling structure includes one or more heat pipes.
Example 13 includes the packaged integrated circuit device of any of Examples 1 to 12, further includes a second semiconductor die; and a second sealed two-phase cooling structure thermally coupled to the second semiconductor die, wherein the mold compound encapsulates the second semiconductor die and the second sealed two-phase cooling structure.
Example 14 includes the packaged integrated circuit device of Example 13, wherein the sealed two-phase cooling structure includes a vapor chamber and the second sealed two-phase cooling structure includes one or more heat pipes.
According to Example 15, a device includes a packaged integrated circuit device that includes a semiconductor die; a sealed two-phase cooling structure thermally coupled to the semiconductor die; and a mold compound encapsulating the semiconductor die and the sealed two-phase cooling structure; and a printed circuit board (PCB) electrically connected to the packaged integrated circuit device.
Example 16 includes the device of Example 15, wherein the packaged integrated circuit device further comprises an interface layer between the sealed two-phase cooling structure and the semiconductor die.
Example 17 includes the device of Example 15 or Example 16, wherein the interface layer includes an adhesive.
Example 18 includes the device of any of Examples 15 to 17, wherein the sealed two-phase cooling structure includes a vapor chamber.
According to Example 19, a method of fabricating a packaged integrated circuit device includes thermally coupling a sealed two-phase cooling structure to a semiconductor die; and using a mold compound to encapsulate the sealed two-phase cooling structure and the semiconductor die.
Example 20 includes the method of Example 19, wherein thermally coupling the sealed two-phase cooling structure to the semiconductor die includes: applying an interface layer on the semiconductor die; and placing the sealed two-phase cooling structure on the interface layer, wherein the mold compound encapsulates the interface layer.
The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. A packaged integrated circuit device comprising:
a semiconductor die;
a sealed two-phase cooling structure thermally coupled to the semiconductor die; and
a mold compound encapsulating the semiconductor die and the sealed two-phase cooling structure.

2. The packaged integrated circuit device of claim 1, further comprising an interface layer between the sealed two-phase cooling structure and the semiconductor die.

3. The packaged integrated circuit device of claim 2, wherein the interface layer includes a layer of mold compound.

4. The packaged integrated circuit device of claim 2, wherein the interface layer includes a thermal interface material.

5. The packaged integrated circuit device of claim 1, wherein the sealed two-phase cooling structure extends past an edge of the semiconductor die.

6. The packaged integrated circuit device of claim 1, wherein a face of the sealed two-phase cooling structure is adjacent to and aligned with a face of the semiconductor die, and wherein the face of the sealed two-phase cooling structure is at least as large as the face of the semiconductor die.

7. The packaged integrated circuit device of claim 1, wherein the sealed two-phase cooling structure includes a vapor chamber.

8. The packaged integrated circuit device of claim 1, wherein the sealed two-phase cooling structure includes one or more heat pipes.

9. The packaged integrated circuit device of claim 1, further comprising a package substrate, the semiconductor die attached to the package substrate, wherein the semiconductor die is between the package substrate and the sealed two-phase cooling structure.

10. The packaged integrated circuit device of claim 1, further comprising a second semiconductor die, wherein the sealed two-phase cooling structure is thermally coupled to the second semiconductor die, and wherein the mold compound encapsulates the second semiconductor die.

11. The packaged integrated circuit device of claim 1, further comprising a second sealed two-phase cooling structure thermally coupled to the semiconductor die, wherein the mold compound encapsulates the second sealed two-phase cooling structure.

12. The packaged integrated circuit device of claim 11, wherein the sealed two-phase cooling structure includes a vapor chamber and the second sealed two-phase cooling structure includes one or more heat pipes.

13. The packaged integrated circuit device of claim 1, further comprising:
a second semiconductor die; and
a second sealed two-phase cooling structure thermally coupled to the second semiconductor die, wherein the mold compound encapsulates the second semiconductor die and the second sealed two-phase cooling structure.

14. The packaged integrated circuit device of claim 13, wherein the sealed two-phase cooling structure includes a vapor chamber and the second sealed two-phase cooling structure includes one or more heat pipes.

15. A device comprising:
a packaged integrated circuit device comprising:
a semiconductor die;
a sealed two-phase cooling structure thermally coupled to the semiconductor die; and
a mold compound encapsulating the semiconductor die and the sealed two-phase cooling structure; and
a printed circuit board (PCB) electrically connected to the packaged integrated circuit device.

16. The device of claim 15, wherein the packaged integrated circuit device further comprises an interface layer between the sealed two-phase cooling structure and the semiconductor die.

17. The device of claim 16, wherein the interface layer includes an adhesive.

18. The device of claim 15, wherein the sealed two-phase cooling structure includes a vapor chamber.

19. A method of fabricating a packaged integrated circuit device, the method comprising:
thermally coupling a sealed two-phase cooling structure to a semiconductor die; and
using a mold compound to encapsulate the sealed two-phase cooling structure and the semiconductor die.

20. The method of claim 19, wherein thermally coupling the sealed two-phase cooling structure to the semiconductor die includes:
applying an interface layer on the semiconductor die; and
placing the sealed two-phase cooling structure on the interface layer, wherein the mold compound encapsulates the interface layer.
